(19) United States
(12) Patent Application Publication
(10) Pub. No.: US 2026/0033301 A1
(43) Pub. Date: Jan. 29, 2026

(54) METHOD FOR FORMING SELF-TRANSFORMED SUPPORT PLATES IN SHALLOW TRENCH ISOLATION FOR ADVANCED SEMICONDUCTOR DEVICES

(71) Applicant: Nanya Technology Corporation, New Taipei City (TW)

(72) Inventor: Da-Zen CHUANG, Taipei City (TW)

(73) Assignee: Nanya Technology Corporation, New Taipei City (TW)

(21) Appl. No.: 18/786,980

(22) Filed: Jul. 29, 2024

(51) Int. Cl. H01L 21/762; H01L 21/02; H01L 21/3105; H01L 21/768; H01L 27/02

(52) U.S. Cl. CPC H01L 21/76224; H01L 21/02164; H01L 21/31053; H01L 21/76816; H01L 21/76831; H10D 89/10

(57) ABSTRACT

The present invention provides a method for forming self-transformed support plates in shallow trench isolation for advanced semiconductor devices, in which after a photolithography process to define active areas on a silicon substrate, an additional photomask is implemented to add a support plate patterning layer in areas where silicon will be etched during a STI etching step to form STI trenches. Tiny silicon support plates inside the STI trenches are formed after the silicon etching. These silicon support plates may provide mechanical support to hold neighboring patterned strips where the active areas are defined or neighboring active areas islands, and preventing them from bending, deformed or shifting. An alignment of photomask pattern at following photolithography process is eased.

### BACKGROUND OF THE INVENTION

### Field of the Invention

The present invention relates to the field of semiconductor process, and more particularly to a semiconductor process capable of providing mechanical support to hold semiconductor structures during formation of shallow trench isolation for advanced semiconductor devices.

### Description of the Prior Art

For advanced semiconductor memory IC, such as DRAM, further pushing of geometry has made manufacture of such IC getting extremely difficult. Take DRAM for instance, sizes of patterned active area (AA) islands are so tiny that they tend to bend or shift from their ideal positions on a semiconductor substrate during the formation of shallow trench isolation (STI), for example, as shown in FIG. 1A and FIG. 1B. FIG. 1A shows active area islands 101 shift to locations 102 from a top view. And, FIG. 1B shows bending of the active area island 102 circled by a dotted line area 104 from a cross sectional view. This makes following steps, especially alignment of photolithography, difficult. In addition, the active area islands 102 may get too close to each other and cause electrical short. All these issues result in lower yield.

Same thing may happen on a strip-type STI, which separates the manufacture of STI into two steps, one step to form the STI at the X axis direction and another step to form the STI at the Y axis direction. Please see FIG. 1C, there is also a possibility of deformed or bending of a hard mask strip 105 as shown by dotted lines 106 after etching shallow trenches in a semiconductor substrate. This also makes following steps, especially alignment of photolithography, difficult and therefore results in lower yield. To solve the above problem, the present invention provides a method for forming shallow trench isolation during the method process self-transformed support plates are provided in shallow trenches to hold semiconductor structures and prevent them from bending or deformed.

### SUMMARY OF THE INVENTION

The present invention aims to provide a method for forming self-transformed support plates in shallow trench isolation for advanced semiconductor devices to prevent hard mask strips where active area are to be defined or hard mask active area islands from bending or shifting from their ideal positions during a shallow trench isolation (STI) formation stage so that alignment of a following photolithography process is eased, and process window and yield can then be enlarged significantly.

In one exemplary embodiment, the present invention provides a method for forming self-transformed support plate in shallow trench isolation for advanced semiconductor memory device. In this embodiment, a silicon substrate is provided and a first dielectric layer is formed on the silicon substrate. A shallow trench isolation patterning layer is formed on the first dielectric layer. Then, etching the first dielectric layer unprotected by the shallow trench isolation patterning layer to expose the silicon substrate. Removing the shallow trench isolation patterning layer such that a patterning first dielectric layer is provided, wherein an area occupied by the patterning first dielectric layer is to define active areas for the semiconductor devices. A shallow trench isolation support plate patterning layer is formed on the exposed silicon substrate. Etching the silicon substrate unprotected by the shallow trench isolation support plate patterning layer and the patterning first dielectric layer such that a plurality of shallow trench and a plurality of silicon support plate are provided, wherein the silicon support plates support are provided in the shallow trenches and supporting the patterning first dielectric layer neighboring the silicon support plates. Removing the shallow trench isolation support plate patterning layer. Then, a thermal oxidation process is executed such that a silicon dioxide liner layer is formed along each of the shallow trenches and the silicon support plates are self-transformed to silicon dioxide support plates in the shallow trenches. A silicon dioxide deposition process is performed to fill the shallow trenches. A chemical mechanical polish process is performed to form a shallow trench isolation structure.

In another exemplary embodiment, wherein the step for forming the shallow trench isolation patterning layer is to form a shallow trench isolation patterning layer along a first dimension or a shallow trench isolation patterning layer along a first dimension and a second dimension which is perpendicular to the first dimension.

In another exemplary embodiment, wherein the step for forming a shallow trench isolation patterning layer along a first dimension is to form the shallow trench isolation patterning layer following a pre-planned layout and paths of recess transistors and buried word lines to be formed, so that the supporting plates would form at the pre-planned layout and paths of recess transistors and buried word lines to be formed. Then, during a process for the formation of the recess transistors and buried word lines, the supporting plates may be removed by etching trenches in which the recess transistors and buried word lines are to be formed.

Also, in one aspect of the present invention, a semiconductor structure with support plates in shallow trenches is provided, which comprises a plurality of active area island on a semiconductor substrate, a plurality of shallow trench divides the plurality of active area islands and a plurality of support plates along a first dimension inside the shallow trenches; wherein each of the active area islands adjoins at least one of the support plates and is held by the support plates adjoining thereto.

Further, in still one another aspect of the present invention, a semiconductor structure with support plates in shallow trenches is provided, which comprises a plurality of active area island on a semiconductor substrate, a plurality of shallow trench divides the plurality of active area islands, and a plurality of support plates along a first dimension and a second dimension perpendicular to the first dimension inside the shallow trenches; wherein each of the active area islands adjoins at least one of the support plates in the first dimension and at least one of the support plates in the second dimension and is held by the support plates adjoining thereto.

### BRIEF DESCRIPTION OF THE DRAWINGS

Other objects and advantages of the invention will become apparent upon reading the following detailed description and upon reference to the accompanying drawings in which:

FIG. 1A is a schematic top view of a prior art semiconductor substrate structure with active area island shifting.

FIG. 1B is a schematic cross sectional view along a Y cutting line of FIG. 1A.

FIG. 1C is a schematic top view of a prior art semiconductor substrate structure with strip-type STI bending.

FIG. 2A through FIG. 8A are respective schematic top views of a semiconductor structure at various stages of a method for forming self-transformed support plate in shallow trench isolation for advanced semiconductor memory devices according to a first embodiment of the present invention.

FIG. 2B through FIG. 8B are schematic cross sectional views along a Y cutting line of FIG. 2A through FIG. 8A, respectively.

FIG. 2C through FIG. 8C are schematic cross sectional views along an X cutting line of FIG. 2A through FIG. 8A, respectively.

FIG. 9 is a schematic top view of a semiconductor structure with support plates in shallow trench isolation according to a second embodiment of the present invention.

FIG. 10A is a schematic top view of a semiconductor structure with support plates in shallow trench isolation according to a third embodiment of the present invention.

FIG. 10A-1 is a schematic top view of a semiconductor structure at a process stage of the third embodiment of the present invention.

FIG. 10A-2 is a schematic cross sectional views along a Y cutting line of FIG. 10A-1.

FIG. 10A-3 is a schematic cross sectional views along an X cutting line of FIG. 10A-1.

FIG. 10B is a schematic top view of a semiconductor structure with support plates in shallow trench isolation according to a fourth embodiment of the present invention.

### DETAILED DESCRIPTION OF THE PREFERRED EMBODIMENTS

The present invention will now be described by way of preferred embodiments with references to the accompanying drawings. Like numerals refer to corresponding parts of various drawings. Please note well-known circuits, structures and techniques may not be shown in detail in order not to obscure the aspects of the disclosure. Various embodiments will be disclosed herein. However, it is to be understood that the disclosed embodiments are only used as an illustration that can be embodied in various forms. In addition, each of the examples given in connection with the various embodiments are intended to be illustrative but not limiting to. Further, the figures are not necessarily conform to the sizes and dimension ratios of actual structures, and some features are magnified to show details of particular components (and any dimensions, materials, and similar details shown in the figures are intended to be illustrative and not limiting to). Therefore, the particular structural and functional details are disclosed herein are not interpreted as limitations, but are used only to teach those skilled in the relevant field technicians to practice the basis of the disclosed embodiments.

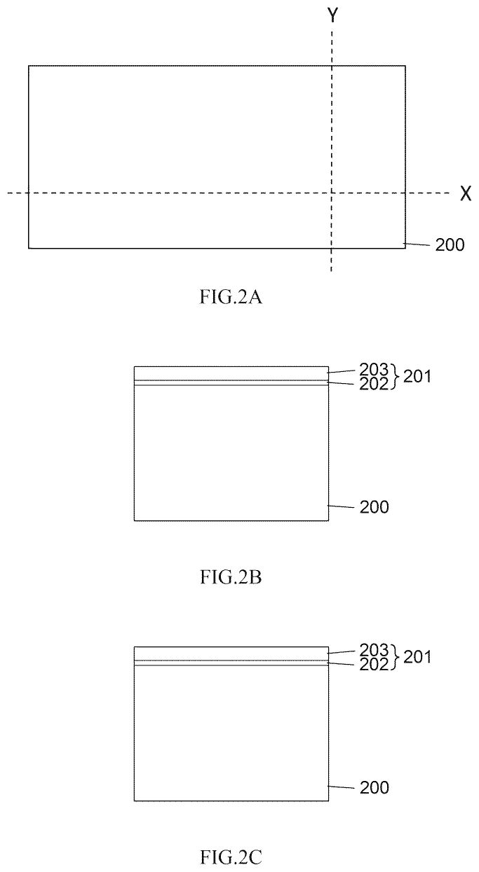

According to the first embodiment of the present invention, FIG. 2A, FIG. 2B and FIG. 2C show a semiconductor structure at a first stage of a method for forming self-transformed support plates in shallow trench isolation for advanced semiconductor devices. FIG. 2A is a schematic top view of the semiconductor structure, FIG. 2B is a schematic cross sectional view along the Y cutting line of FIG. 2A and FIG. 2C is a schematic cross sectional view along the X cutting line of FIG. 2A.

In the first stage of the method for forming self-transformed support plates in shallow trench isolation for advanced semiconductor devices according to the first embodiment of the present invention, a silicon substrate 200 is provided and a first dielectric layer 201 is formed on the silicon substrate 200. The step of forming the first dielectric layer 201 on the silicon substrate 200 may further comprise forming a silicon dioxide layer 202 on the silicon substrate 200 for example by thermal oxidation and forming a silicon nitride layer 203 on the silicon dioxide layer 202.

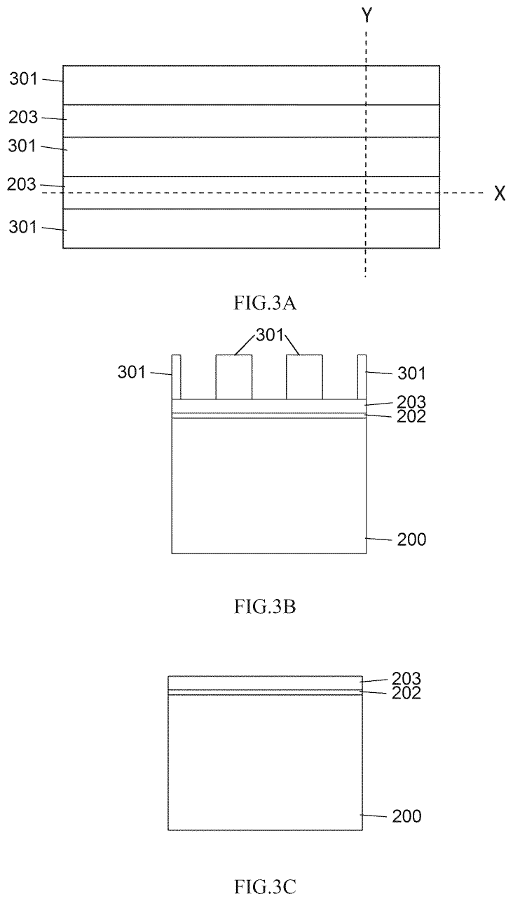

FIG. 3A is a schematic top view of a semiconductor structure at a second stage of the method for forming self-transformed support plates in shallow trench isolation for advanced semiconductor devices according to the first embodiment of the present invention. FIG. 3B is a schematic cross sectional view along the Y cutting line of FIG. 3A and FIG. 3C is a schematic cross sectional view along the X cutting line of FIG. 3A.

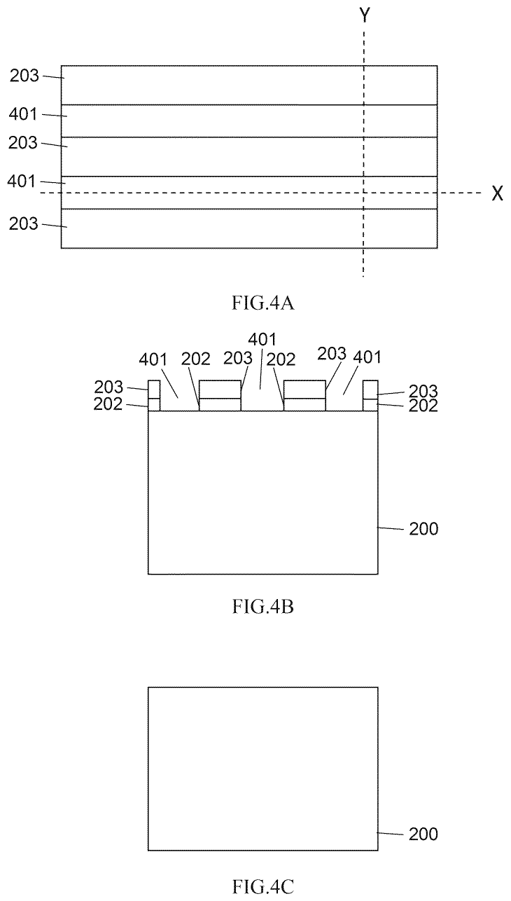

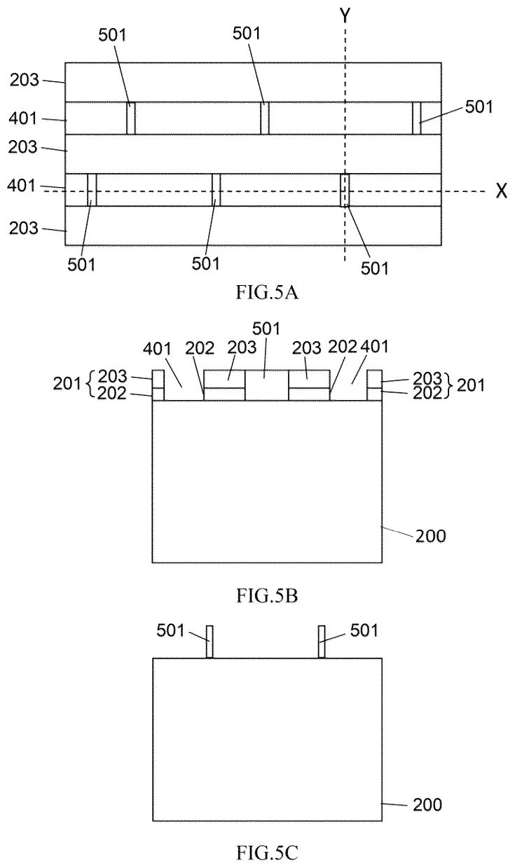

FIG. 4A is a schematic top view of a semiconductor structure at a third stage of the method for forming self-transformed support plates in shallow trench isolation for advanced semiconductor devices according to the first embodiment of the present invention. FIG. 4B is a schematic cross sectional view along the Y cutting line of FIG. 4A and FIG. 4C is a schematic cross sectional view along the X cutting line of FIG. 4A.

In the second and third stages of the method for forming self-transformed support plates in shallow trench isolation for advanced semiconductor devices according to the first embodiment of the present invention, a plurality of first trench 401 along the X direction in the first dielectric layer 201 is formed. As shown in FIG. 3A, in the second stage, a shallow trench isolation patterning layer 301 is provided on the first dielectric layer 201. Where the shallow trench isolation patterning layer 301 is provided in an interspaced-strips form along the X direction to expose portions of the first dielectric layer 201.

Please refer to FIG. 4A, FIG. 4B and FIG. 4C, in the third stage of the method for forming self-transformed support plates in shallow trench isolation for advanced semiconductor devices according to the first embodiment of the present invention, the first trenches 401 are formed on the silicon substrate 200 along the X direction by etching the first dielectric layer 201 unprotected by the shallow trench isolation patterning layer 301. Then remove the shallow trench isolation patterning layer 301. Wherein areas occupied by the first dielectric layer 201 after etching are to define active areas of the silicon substrate 200.

FIG. 5A is a schematic top view of a semiconductor structure at a fourth stage of the method for forming self-transformed support plates in shallow trench isolation for advanced semiconductor devices according to the first embodiment of the present invention. FIG. 5B is a schematic cross sectional view along the Y cutting line of FIG. 5A and FIG. 5C is a schematic cross sectional view along the X cutting line of FIG. 5A.

In the fourth stage of the method for forming self-transformed support plates in shallow trench isolation for advanced semiconductor devices according to the first embodiment of the present invention, forming a shallow trench isolation support plate patterning layer 501 on the exposed silicon substrate 200.

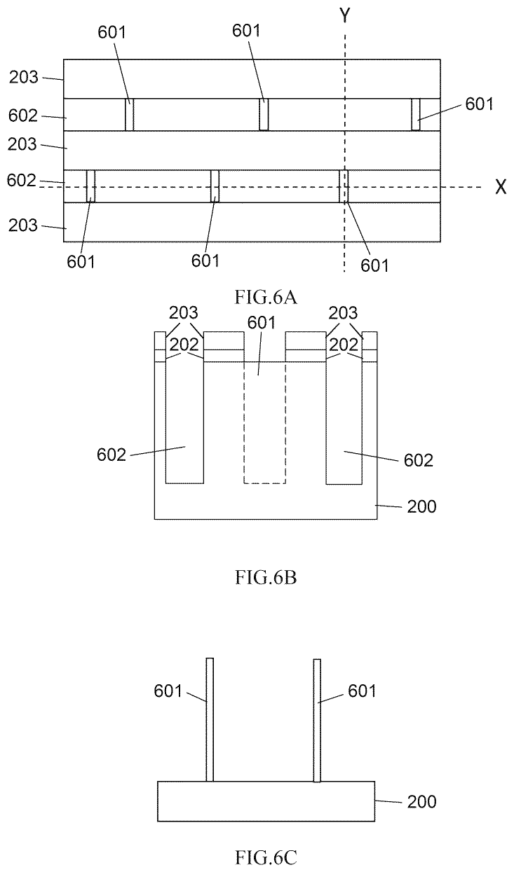

FIG. 6A is a schematic top view of a semiconductor structure at a fifth stage of the method for forming self-transformed support plates in shallow trench isolation for advanced semiconductor devices according to the first embodiment of the present invention. FIG. 6B is a schematic cross sectional view along the Y cutting line of FIG. 6A and FIG. 6C is a schematic cross sectional view along the X cutting line of FIG. 6A.

In the fifth stage of the method for forming self-transformed support plates in shallow trench isolation for advanced semiconductor devices according to the first embodiment of the present invention, etching the silicon substrate 200 unprotected by the shallow trench isolation support plate patterning layer 501 and the strip type first dielectric layer 201 to form a plurality of shallow trench 602 and a plurality of silicon support plate 601 along the X dimension, wherein the silicon support plates 601 are formed in the shallow trenches 602 and supporting the shallow trenches 602. In other words, the silicon support plates 601 inside the shallow trenches 602 provides mechanical support to hold neighboring strip type first dielectric layer 201 and prevent the neighboring strip type first dielectric layer 201 from bending or deformed. Then, the shallow trench isolation support plate patterning layer 501 is removed.

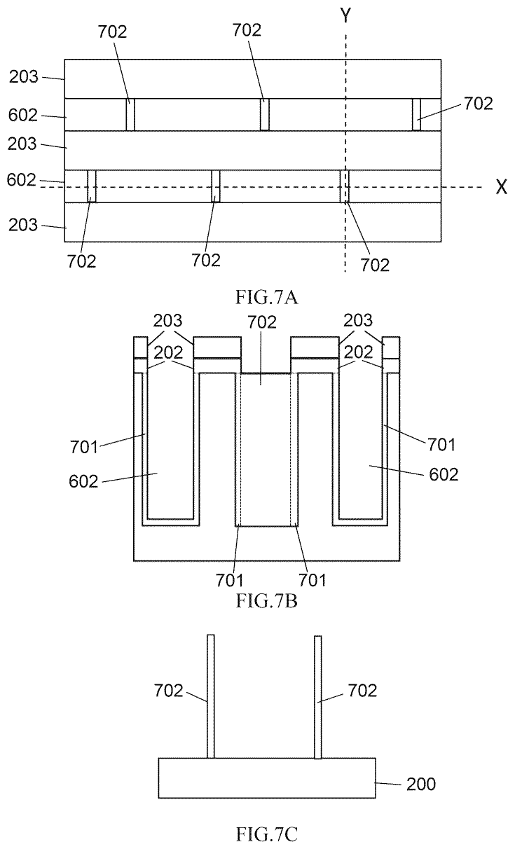

FIG. 7A is a schematic top view of a semiconductor structure at a sixth stage of the method for forming self-transformed support plates in shallow trench isolation for advanced semiconductor devices according to the first embodiment of the present invention. FIG. 7B is a schematic cross sectional view along the Y cutting line of FIG. 7A and FIG. 7C is a schematic cross sectional view along the X cutting line of FIG. 7A.

In the sixth stage of the method for forming self-transformed support plates in shallow trench isolation for advanced semiconductor devices according to the first embodiment of the present invention, performing a thermal oxidation process such that a silicon dioxide liner layer 701 grows around each of the shallow trenches 602 and all the silicon of the silicon support plates 601 are consumed and the supporting plate material is transformed from silicon to silicon dioxide to form self-transformed silicon dioxide support plates 702 in the shallow trenches 602. Wherein the silicon dioxide liner layer 701 would become one with the silicon dioxide layer 202. The silicon dioxide support plates 702 inside the shallow trenches 602 still provides mechanical support to hold neighboring strip type first dielectric layer 201 and prevent the neighboring strip type first dielectric layer 201 from bending or deformed.

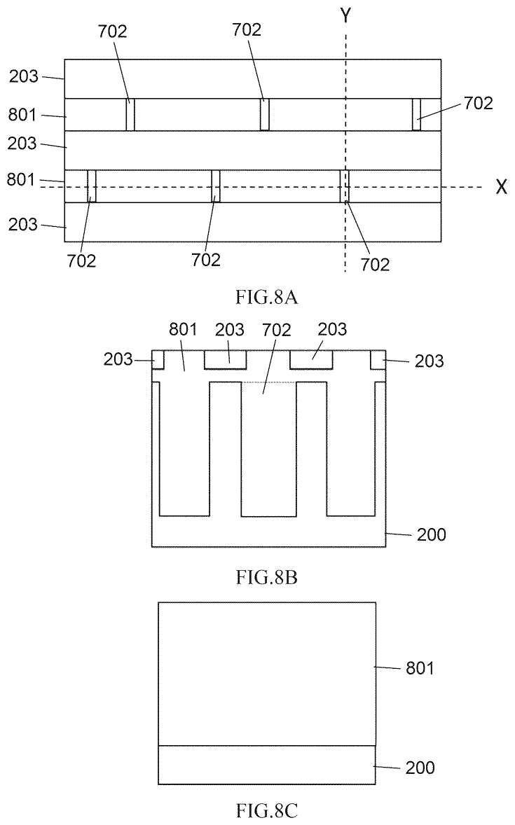

FIG. 8A is a schematic top view of a semiconductor structure at a seventh stage of the method for forming self-transformed support plates in shallow trench isolation for advanced semiconductor devices according to the first embodiment of the present invention. FIG. 8B is a schematic cross sectional view along the Y cutting line of FIG. 8A and FIG. 8C is a schematic cross sectional view along the X cutting line of FIG. 8A.

In the seventh stage of the method for forming self-transformed support plates in shallow trench isolation for advanced semiconductor devices according to the first embodiment of the present invention, performing a silicon dioxide deposition process to fill the shallow trenches 602 with silicon dioxide 801 and performing a chemical mechanical polish process to form a shallow trench isolation structure.

In the seventh stage, silicon dioxide support plates 702 would become part of the shallow trench isolation structure with no need of any step to remove it, which makes the whole process and structure simple. Furthermore, the density of silicon dioxide support plates 702 in the shallow trench isolation structure could be adjusted, either dense or loose, based on the need of the process and devices.

One skilled artisan in the field from the disclosure of the above would learn that the generated support plates, no matter is in silicon form or in transformed silicon dioxide form, it always stays inside the STI trenches to provide mechanical support. Therefore, the bending, shifting, or deforming of active area strips or active area islands during the whole STI process can be suppressed. Process window and yield can then be enlarged significantly.

Still, in the regular shallow trench isolation process, silicon dioxide which is an insulator is usually used to fill the STI trenches to generate isolation among active area strips or islands. In the present invention, the material of support plates has transformed from silicon into silicon dioxide during the STI process, so the isolation purpose of STI still intact.

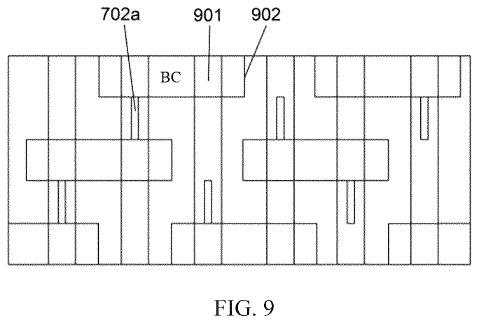

Please refer to FIG. 9 showing a schematic top view of a semiconductor structure according to a second embodiment of the present invention, in which steps for forming self-transformed support plates in shallow trench isolation for advanced semiconductor devices are similar to those of the first embodiment, while according to the second embodiment, locations for forming self-transformed support plates in shallow trench isolation for advanced semiconductor devices follow a layout and paths of recess transistors and buried word lines to be formed. Please note one skilled artisan in the field would know that the layout and paths of the recess transistors and buried word lines may be planned in advanced. For example, in a corresponding fourth stage of the second embodiment, a shallow trench isolation support plate patterning layer is formed along the pre-planned layout and paths 901 of the recess transistors and buried word lines to be formed so that in subsequent steps supporting plates 702a are formed along the pre-planned layout and paths 901 of the recess transistors and buried word lines to be formed.

Then, after a corresponding seventh stage of the second embodiment, etching a plurality of trench along the pre-planned layout and paths 901 to remove the supporting plates 702a. In case that transformation of silicon into silicon dioxide for the supporting plates 702a at a corresponding sixth stage of the second embodiment is incomplete and leave portion of the supporting plates 702a still in form of silicon, the leftover silicon can be removed at the step for etching the plurality of trench along the pre-planned layout and paths 901. Moreover, during the etching of the plurality of trench, a shallow trench isolation structure filled with silicon dioxide around the strip-type first dielectric layer 201 would provide mechanical support for it. A patterning and etching process to the strip-type first dielectric layer 201 may follow to form a plurality of active area islands 902 supported by the supporting plates 702a. Processes for forming the recess transistors and buried word lines located at the pre-planned layout and paths 901 may follow. Alternatively, one skilled artisan in the field would learn that the process stage for the recess transistors and buried word lines may follow the etching of the trenches along the pre-planned layout and paths 901.

Applications of this invention is not limited to the STI structure described above, which separates the formation of STI into STI in X direction and that in Y direction. Namely, the STI etch and following silicon oxide filling have to be executed twice. For those processing STI etch and following silicon oxide filling in one time, this invention can also be applied, to support active area islands without bending or shifting, so that the alignment of patterns at following photomask steps can be greatly improved.

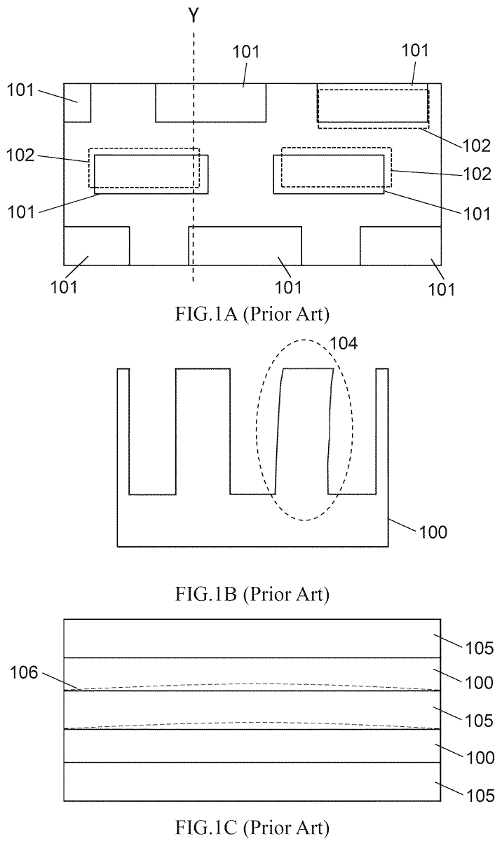

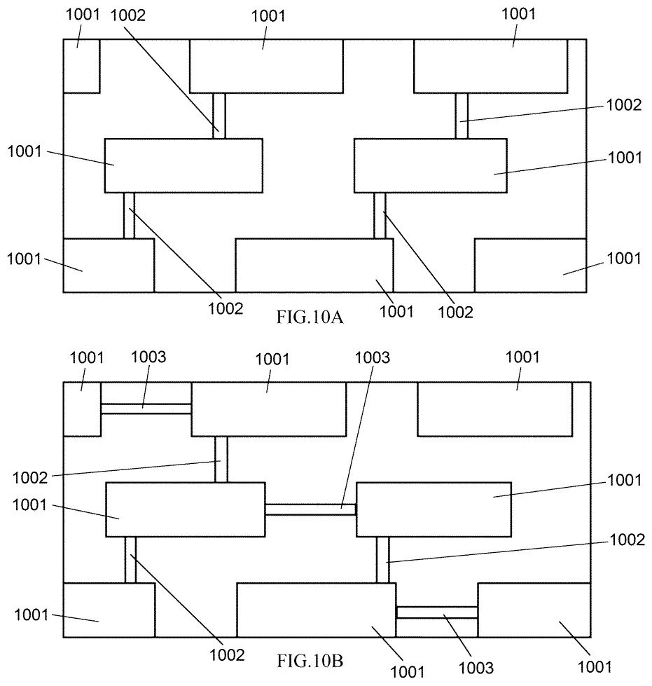

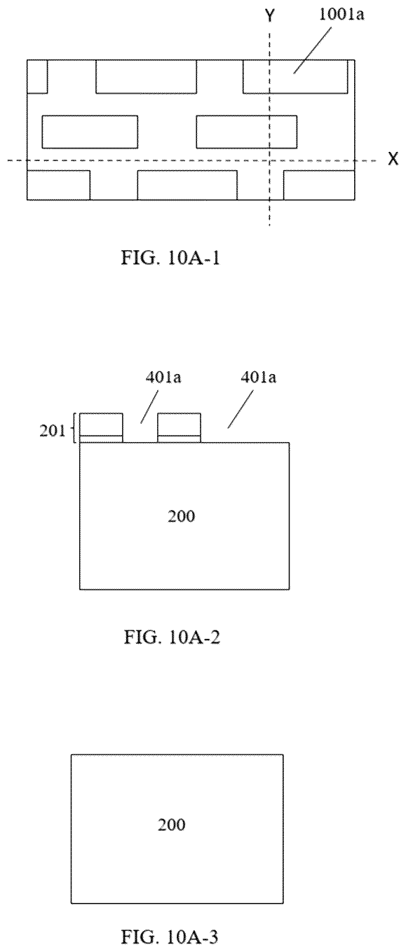

Please refer to FIG. 10A, which is a schematic top view of a semiconductor structure according to a third embodiment of the present invention. Similar process steps corresponding to FIG. 2 through FIG. 7 may be applicable to the third embodiment. For example, please firstly see FIG. 10A-1 to FIG. 10A-3, a shallow trench isolation patterning layer being layout in both X and Y directions is provided on the first dielectric layer 201. Then, performing trench etching to remove the first dielectric layer 201 unprotected by the shallow trench isolation patterning layer to form a plurality of trench 401a in both X and Y directions and a patterned first dielectric layer 1001a divided by the plurality of trench 401a in both X and Y directions to define active areas islands. The silicon substrate 200 are exposed inside the plurality of trench 401a in both X and Y directions. Please note following process steps are not shown in drawings, but one skilled artisan would learn them from the disclosure of the above. Then, a shallow trench isolation support plate patterning layer in Y direction is provided on the exposed silicon substrate 200 inside the plurality of trenches 401a. Executing STI etching to remove portions of the silicon substrate 200 unprotected by the shallow trench isolation support plate patterning layer and the patterned first dielectric layer 1001a. As a result, a plurality of STI silicon supporting plates in Y direction are formed inside the plurality of STI trenches and neighboring the patterned first dielectric layer 1001a. A thermal oxidation process is executed to form a silicon dioxide liner layer along the plurality of STI trench in both X and Y directions. At the same time, the plurality of STI silicon supporting plates in Y direction become self-transformed STI silicon dioxide supporting plates. Then, the patterned first dielectric layer 1001a is removed to expose active area islands 1001 which is supported by the STI silicon dioxide supporting plates 1002 in Y direction, as shown in FIG. 10A.

The STI supporting plates also can be layout and patterned in both X and Y directions to provide extra mechanical support to the active area islands as shown in FIG. 10B, which is a schematic top view of a semiconductor structure according to a fourth embodiment of the present invention. The processes of the fourth embodiment are similar to that of the third embodiment. The difference between them resides in a shallow trench isolation support plate patterning layer in both X and Y directions is provided on the exposed silicon substrate 200 inside the plurality of trenches in both X and Y directions according to the fourth embodiment. Executing STI etching to remove portions of the silicon substrate 200 unprotected by the shallow trench isolation support plate patterning layer and the patterned first dielectric layer. As a result, a plurality of STI silicon supporting plates are formed inside the plurality of STI trenches in both X and Y direction and neighboring the patterned first dielectric layer. A thermal oxidation process is executed to form a silicon dioxide liner layer along the plurality of STI trench in both X and Y directions. At the same time, the plurality of STI silicon supporting plates become self-transformed STI silicon dioxide supporting plates. Then, the patterned first dielectric layer is removed to expose active area islands 1001 which is supported by the STI silicon dioxide supporting plates 1002 in Y direction and the STI silicon dioxide supporting plates 1003 in X direction, as shown in FIG. 10B.

From the disclosure of the above, one skilled artisan in the field would appreciate that the layout of the STI support plates is not limited to one direction, either X direction or Y direction, and can be both of the two directions to provide extra mechanical support and to give engineers more degree of freedom on designing the STI support plates based on the disclosure of the present invention.

The above-mentioned embodiments of the present invention are exemplary and not intended to limit the scope of the present invention. Various variation or modifications made without departing from the spirit of the present invention and achieving equivalent effects shall fall within the scope of claims of the present invention.

What is claimed is:

1. A method for forming self-transformed support plates in shallow trench isolation for advanced semiconductor devices, comprising:
providing a silicon substrate;
forming a first dielectric layer on the silicon substrate;
forming a shallow trench isolation patterning layer on the first dielectric layer;
etching the first dielectric layer unprotected by the shallow trench isolation patterning layer to exposed the silicon substrate;
removing the shallow trench isolation patterning layer such that a patterning first dielectric layer are provided, wherein an area occupied by the patterning first dielectric layer are to define active areas for the semiconductor devices;
forming a shallow trench isolation support plate patterning layer on the exposed silicon substrate;
etching the silicon substrate unprotected by the shallow trench isolation support plate patterning layer and the patterning first dielectric layer such that a plurality of shallow trench and a plurality of silicon support plate are provided, wherein the silicon support plates are provided in the shallow trenches and supporting the patterning first dielectric layer neighboring the silicon support plates;
removing the shallow trench isolation support plate patterning layer; and
performing a thermal oxidation process such that a silicon dioxide liner layer is formed along each of the shallow trenches and the silicon support plates are self-transformed to silicon dioxide support plates in the shallow trenches.

2. The method for forming self-transformed support plates in shallow trench isolation for semiconductor devices of claim 1, further comprising a silicon dioxide deposition process is performed to fill the shallow trenches, and then performing a chemical mechanical polish process to form a shallow trench isolation structure.

3. The method for forming self-transformed support plates in shallow trench isolation for semiconductor devices of claim 1, wherein the step for forming the shallow trench isolation patterning layer is to form a shallow trench isolation patterning layer along a first dimension or a shallow trench isolation patterning layer along a first dimension and a second dimension which is perpendicular to the first dimension.

4. The method for forming self-transformed support plates in shallow trench isolation for semiconductor devices of claim 1, wherein the step for forming a shallow trench isolation support plate patterning layer on the exposed silicon substrate is to form the shallow trench isolation support plate patterning layer following pre-planned layout and paths of recess transistors and buried word lines to be formed.

5. The method for forming self-transformed support plates in shallow trench isolation for semiconductor devices of claim 4, further comprising a silicon dioxide deposition process is performed to fill the shallow trenches, and then performing a chemical mechanical polish process to form a shallow trench isolation structure.

6. The method for forming self-transformed support plates in shallow trench isolation for semiconductor devices of claim 4, wherein the step for etching the silicon substrate unprotected by the shallow trench isolation support plate patterning layer and the patterning first dielectric layer is to form a plurality of trench and a plurality of silicon support plate that follow the pre-planned layout and paths of recess transistors and buried word lines to be formed.

7. The method for forming self-transformed support plates in shallow trench isolation for semiconductor devices of claim 5, wherein subsequent to the formation of the shallow trench isolation structure further comprises a step for etching a plurality of trench along the pre-planned layout and paths of recess transistors and buried word lines to be formed so that the plurality of silicon dioxide support plate is removed.

8. The method for forming self-transformed support plates in shallow trench isolation for semiconductor devices of claim 1, wherein the step of forming the first dielectric layer on the silicon substrate comprises forming a silicon oxide layer on the silicon substrate and forming a silicon nitride layer on the silicon oxide layer.

9. A semiconductor structure with support plates in shallow trenches, comprising:
a plurality of active area island on a semiconductor substrate;
a plurality of shallow trench divides the plurality of active area islands; and
a plurality of support plates along a first dimension inside the shallow trenches;
wherein each of the active area islands adjoins at least one of the support plates
and is held by the support plates adjoining thereto.

10. The semiconductor structure with support plates in shallow trenches of claim 9, wherein the semiconductor substrate is a silicon substrate.

11. The semiconductor structure with support plates in shallow trenches of claim 9, wherein the plurality of shallow trench is along the first dimension and a second dimension perpendicular to the first dimension.

12. The semiconductor structure with support plates in shallow trenches of claim 9, wherein the support plates are silicon dioxide support plates.

13. The semiconductor structure with support plates in shallow trenches, comprising:
a plurality of active area island on a semiconductor substrate;
a plurality of shallow trench divides the plurality of active area islands; and
a plurality of support plates along a first dimension and a second dimension perpendicular to the first dimension inside the shallow trenches;
wherein each of the active area islands adjoins at least one of the support plates in the first dimension and at least one of the support plates in the second dimension and is held by the support plates adjoining thereto.

14. The semiconductor structure with support plates in shallow trenches of claim 13, wherein the semiconductor substrate is a silicon substrate.

15. The semiconductor structure with support plates in shallow trenches of claim 13, wherein the plurality of shallow trench is along the first dimension and the second dimension.

16. The semiconductor structure with support plates in shallow trenches of claim 13, wherein the support plates are silicon dioxide support plates.
